(19) United States
(12) Patent Application Publication
(10) Pub. No.: US 2011/0299020 A1
(43) Pub. Date: Dec. 8, 2011

(54) LIQUID CRYSTAL DISPLAY DEVICE AND METHOD OF MANUFACTURING SAME

(76) Inventor: Minoru Takagi, Osaka (JP)

(21) Appl. No.: 13/201,982

(22) PCT Filed: Feb. 17, 2010
(86) PCT No.: PCT/JP2010/000972

§ 371 Date: Aug. 17, 2011

(30) Foreign Application Priority Data
Feb. 18, 2009 (JP) 2009-034856

(51) Int. Cl. G02F 1/1337; H01L 33/08

(52) U.S. Cl. 349/129; 438/30; 257/E33.012

(57) ABSTRACT

Each pixel of a liquid crystal display device 100 of the present invention includes: a first electrode 12; a second electrode 22; a liquid crystal layer 32 provided between the first electrode and the second electrode; a first vertical alignment film 14 provided between the first electrode and the liquid crystal layer; a second vertical alignment film 24 provided between the second electrode and the liquid crystal layer; and a pair of alignment-sustaining layers 16 and 26 of photopolymerization products 16a and 26a formed on one surface of the first vertical alignment film that is closer to the liquid crystal layer and one surface of the second vertical alignment film that is closer to the liquid crystal layer, wherein the photopolymerization products 16a and 26a of the pair of alignment-sustaining layers each cover 30% or more and 60% or less of an area of the transmission region of a corresponding one of the first and second vertical alignment films 14 and 24. Therefore, it is possible to improve the mass-production stability and the reliability of the liquid crystal display device.

### TECHNICAL FIELD

The present invention relates to a liquid crystal display device and a method for manufacturing the same, and more particularly to a liquid crystal display device using a PSA technique and a method for manufacturing the same.

### BACKGROUND ART

A nature of a liquid crystal display device is that the display quality depends on the viewing angle. Therefore, attempts have been made to increase the viewing angle of a liquid crystal display device by forming a plurality liquid crystal domains in which pretilt directions of liquid crystal molecules are different from each other in each pixel (e.g., the orientation division of the MVA mode, or the like), or by forming liquid crystal domains having liquid crystal molecules oriented in a plurality of pretilt directions different from one another in each pixel (e.g., the axisymmetric alignment domains of the CPA mode).

In recent years, the Polymer Sustained Alignment technology (hereinafter referred to as the “PSA technology”) has been developed as a technique for controlling the pretilt direction of liquid crystal molecules (see Patent Documents 1 and 2 and Non-Patent Document 1). The disclosure of Patent Documents 1 and 2 and Non-Patent Document 1 is incorporated herein by reference in its entirety.

The PSA technology is a technique in which a liquid crystal cell is assembled with a small amount of a polymerizable compound (e.g., a photopolymerizable monomer or oligomer) mixed in a liquid crystal material, after which the polymerizable compound is irradiated with actinic energy rays (e.g., ultraviolet rays) the presence of a predetermined voltage applied to the liquid crystal layer so as to control the pretilt direction of the liquid crystal molecules by means of the formed polymerization product. The alignment of the liquid crystal molecules when the polymerization product is formed is sustained (memorized) even after the voltage is removed (in the absence of an applied voltage). Therefore, the PSA technology has an advantage that the pretilt azimuth and the pretilt angle of the liquid crystal molecules can be adjusted by controlling the electric field, or the like, formed in the liquid crystal layer. Since the PSA technology does not require a rubbing treatment, it is particularly suitable for forming a vertical alignment liquid crystal layer, with which it is difficult to control the pretilt direction by a rubbing treatment.

### CITATION LIST

### Patent Literature

Patent Document No. 1: Japanese Laid-Open Patent Publication No. 2002-357830

Patent Document No. 2: Japanese Laid-Open Patent Publication No. 2006-78968

### Non-Patent Literature

[Non-Patent Document 1] K. Hanaoka et al. “A New MVA-LCD by Polymer Sustained Alignment Technology”, SID 04 DIGEST 1200-1203 (2004)

### SUMMARY OF INVENTION

### Technical Problem

However, a study by the present inventor on the mass-production stability and the reliability of liquid crystal display devices using the PSA technology revealed the following problems: (1) the pretilt angle of the liquid crystal molecules is not stable and display non-uniformity is observed; and (2) display burn-in occurs over time using the liquid crystal display device.

The present invention has been made to solve the problems described above, and an object thereof is to improve the mass-production stability and the reliability of liquid crystal display devices using the PSA technology.

### Solution to Problem

A liquid crystal display device of the present invention includes a plurality pixels each having a transmission region, each of the plurality of pixels including: a first electrode; a second electrode; a liquid crystal layer provided between the first electrode and the second electrode; a first vertical alignment film provided between the first electrode and the liquid crystal layer; a second vertical alignment film provided between the second electrode and the liquid crystal layer; and a pair of alignment-sustaining layers of photopolymerization products formed on one surface of the first vertical alignment film that is closer to the liquid crystal layer and one surface of the second vertical alignment film that is closer to the liquid crystal layer, wherein the photopolymerization product of each of the pair of alignment-sustaining layers covers 30% or more and 60% or less of an area of the transmission region of a corresponding one of the first and second vertical alignment films.

In an embodiment, the liquid crystal layer includes a nematic liquid crystal material having a negative dielectric anisotropy and a photopolymerizable compound for forming the photopolymerization product, wherein a content of the photopolymerizable compound is greater than 0.015% by mass and less than 0.068% by mass of the liquid crystal material.

In an embodiment, the photopolymerization product substantially includes only particles whose particle diameter is 500 nm or less.

In an embodiment, the photopolymerizable compound includes diacrylate or dimethacrylate.

A method for manufacturing a liquid crystal display device of the present invention is a method for manufacturing any of the liquid crystal display devices set forth above, including the steps of: (a) providing a liquid crystal cell including a first substrate having the first electrode and the first vertical alignment film formed thereon, a second substrate having the second electrode and the second vertical alignment film formed thereon, and a mixture of a nematic liquid crystal material and a photopolymerizable compound between the first substrate and the second substrate; (b) irradiating the mixture with light in presence of a voltage applied between the first electrode and the second electrode to form the photopolymerization product so as to cover an area of 15% or more of the transmission region of one surface of each of the first and second vertical alignment films that is closer to the liquid crystal layer; and (c) further irradiating the mixture with light in absence of a voltage applied between the first electrode and the second electrode after the step (b) to further form the photopolymerization product so as to cover an area of 30% or more of the transmission region of one surface of each of the first and second vertical alignment films that is closer to the liquid crystal layer.

In an embodiment, content of the photopolymerizabie compound in the mixture is in a range of 0.15% by mass or more and 0.40% by mass or less of the liquid crystal material in the step (a).

### Advantageous Effects of Invention

According to the present invention, it is possible to improve the mass-production stability and the reliability of a liquid crystal display device using the PSA technology.

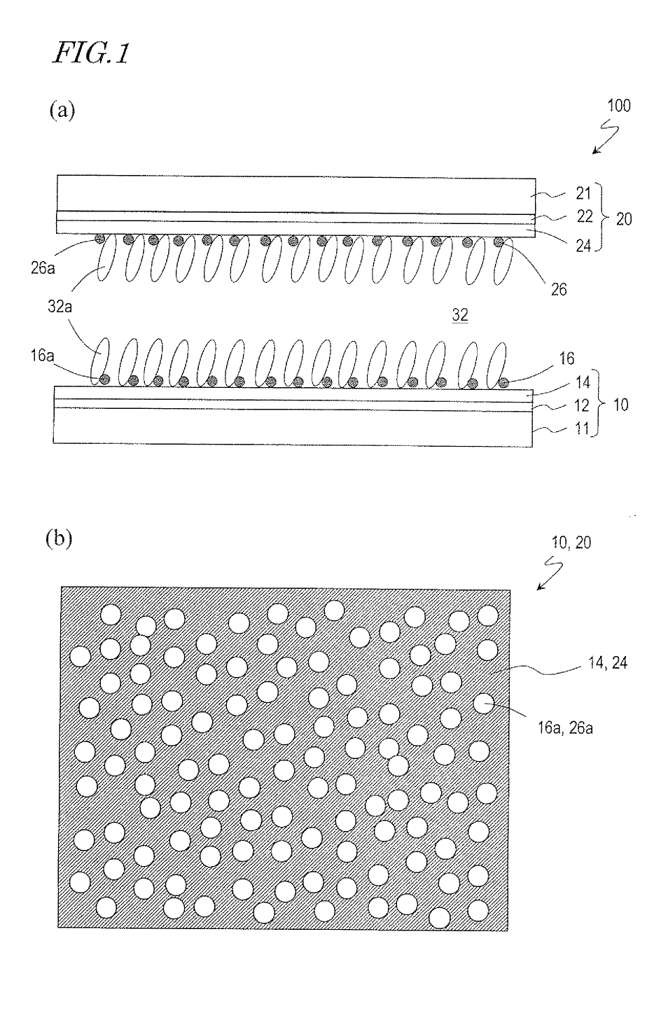

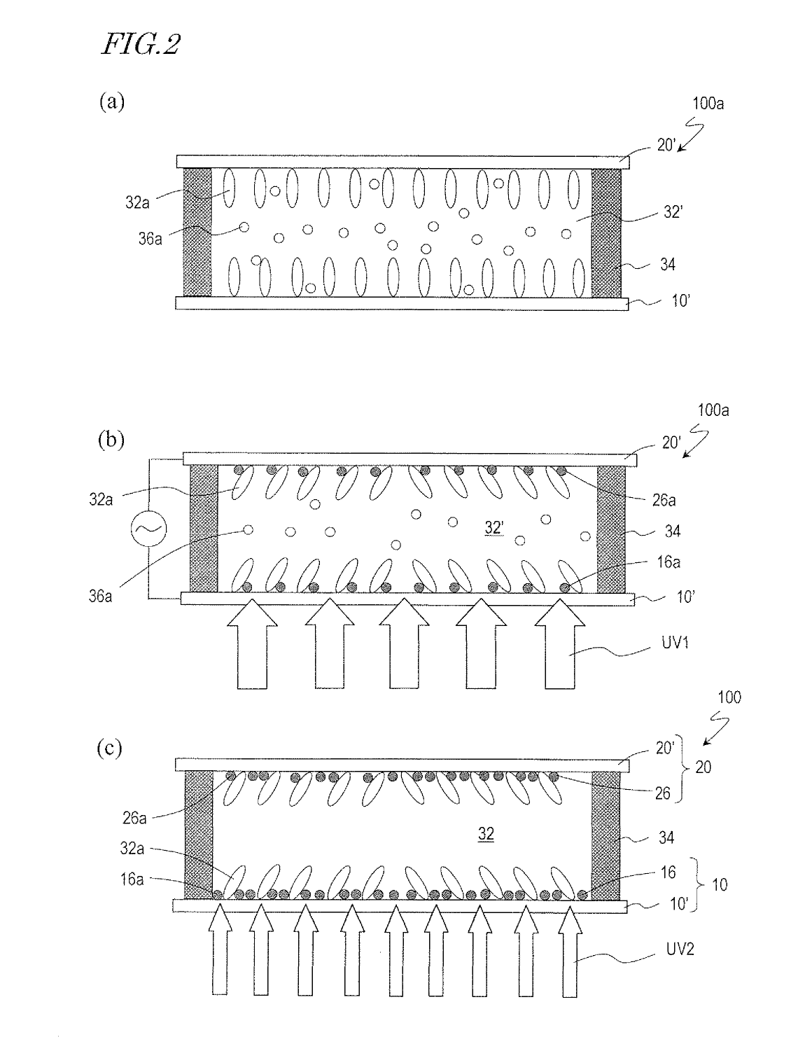

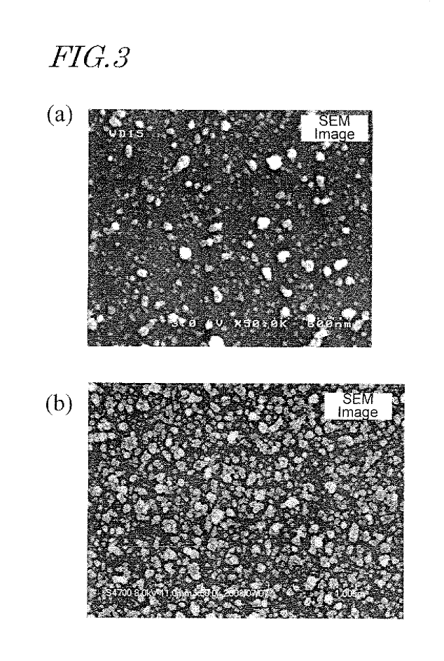

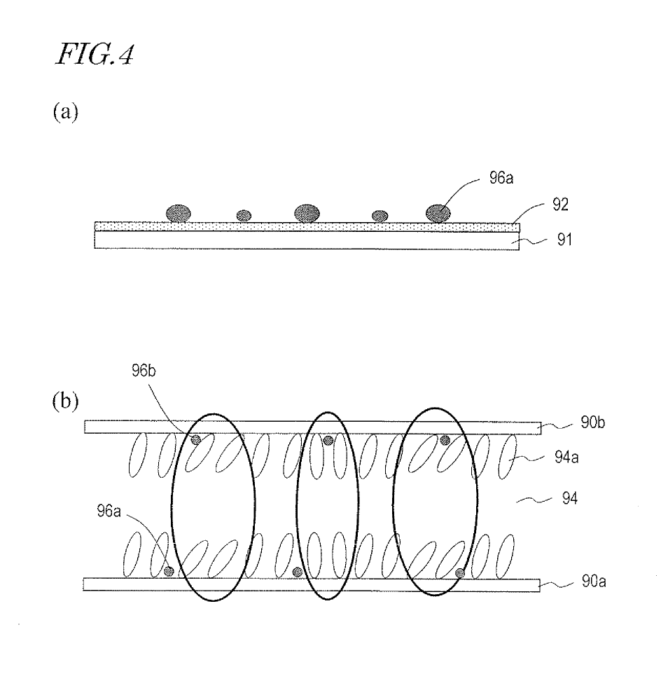

### BRIEF DESCRIPTION OF DRAWINGS

[FIGS. 1(a) and (b) are diagrams showing a structure of a liquid crystal display device 100 according to an embodiment of the present invention, wherein (a) is a schematic cross-sectional view of the liquid crystal display device 100, and (b) is a schematic plan view showing one surface of a substrate 10 or 20 of the liquid crystal display device 100 that is closer to the liquid crystal layer.

[FIG. 2](a)-(c) are schematic cross-sectional views illustrating a method for manufacturing the liquid crystal display device 100 according to an embodiment of the present invention.

[FIGS. 3](a) and (b) are views showing how an alignment-sustaining layer is formed in a method for manufacturing the liquid crystal display device 100 according to an embodiment of the present invention, wherein (a) shows an SEM image showing the condition on the alignment film after a first light irradiation step, and (b) shows an SEM image showing the condition on the alignment film after a second light irradiation step.

[FIGS. 4](a) and (b) are schematic diagrams illustrating problems of a conventional liquid crystal display device, wherein (a) is a schematic cross-sectional view showing photopolymerization product formed on the substrate, and (b) is a cross-sectional view schematically showing the pretilt of liquid crystal molecules being disturbed.

### DESCRIPTION OF EMBODIMENTS

A structure of a liquid crystal display device according to an embodiment of the present invention will now be described with reference to the drawings. While a transmission liquid crystal display device in which each pixel is formed only by a transmission region where display is produced in the transmission mode will be illustrated herein, the liquid crystal display device according to an embodiment of the present invention is also applicable to a transmission-reflection or transflective liquid crystal display device where each pixel includes a reflection region where display is produced in the reflection mode and a transmission region where display is produced in the transmission mode.

A configuration of a liquid crystal display device 100 according to an embodiment of the present invention will be described with reference to FIGS. 1(a) and 1(b). FIG. 1 shows a structure within one pixel of the liquid crystal display device 100, i.e., the composition of a region where liquid crystal molecules have a predetermined pretilt.

FIG. 1(a) is a schematic cross-sectional view of the liquid crystal display device 100, and FIG. 1(b) is a schematic plan view of one surface of a substrate 10 or 20 of the liquid crystal display device 100 that is closer to the liquid crystal layer.

The liquid crystal display device 100 includes the first substrate 10, the second substrate 20, and a liquid crystal layer 32 provided between the first substrate 10 and the second substrate 20. The first substrate 10 is a TFT substrate, for example, and the second substrate 20 is a color filter substrate, for example. For example, the first substrate 10 includes a glass substrate 11, a first electrode (e.g., a pixel electrode) 12 formed on the glass substrate 11, a first vertical alignment film 14 formed on one side of the first electrode 12 that is closer to the liquid crystal layer 32, and a first alignment-sustaining layer 16 formed on one surface of the first vertical alignment film 14 that is closer to the liquid crystal layer 32. For example, the second substrate 20 includes a glass substrate 21, a second electrode (e.g., a counter electrode) 22 formed on the glass substrate 21, a second vertical alignment film 24 formed on one side of the second electrode 22 that is closer to the liquid crystal layer 32, and a second alignment-sustaining layer 26 formed on one surface of the second vertical alignment film 24 that is closer to the liquid crystal layer 32.

Each of the first alignment-sustaining layer 16 and the second alignment-sustaining layer 26 is formed by the PSA technology and is formed by photopolymerization product, and the first alignment-sustaining layer 16 and the second alignment-sustaining layer 26 each cover 30% or more and 60% or less of the area of pixels of a corresponding one of the first vertical alignment film 14 and the second vertical alignment film 24. As will later be described with some of the experimental results, it is possible to improve the mass-production stability and the reliability of the liquid crystal display device 100 if the first alignment-sustaining layer 16 and the second alignment-sustaining layer 26 each cover 30% or more and 60% or less of the area of the transmission region of a corresponding one of the first vertical alignment film 14 and the second vertical alignment film 24.

As schematically shown in FIG. 1(b), a large number of photopolymerization product particles 16a and 26a are formed on one surface of the vertical alignment film 14 that is closer to the liquid crystal layer and one surface of the vertical alignment film 24 that is closer to the liquid crystal layer. The photopolymerization product particles 16a and 26a form the alignment-sustaining layers 16 and 26. Here, it is preferred that the photopolymerization product particles 16a and 26a substantially include only particles whose particle diameter is 500 nm or less.

As schematically shown in FIG. 4(a), if there is a polymerization product particle 96a whose particle diameter is greater than 500 nm on a vertical alignment film 92 of a substrate 91, the alignment of the liquid crystal molecules may be disturbed or it may be presented as a bright spot when display is produced. Where the polymerization product particle 96a whose particle diameter is greater than 500 nm is formed, the area covered by the polymerization product particle 96a is often less than 30%. As a result, as shown FIG. 4(b), the orientation of liquid crystal molecules 94a of a liquid crystal layer 94 provided between substrates 90a and 90b with such polymerization products 96a and 96b formed on the surface thereof may be disturbed depending on the location, causing display non-uniformity.

Note that while a transmission liquid crystal display device where pixels only have transmission regions is illustrated herein, if the pixels have reflection regions (i.e., in the case of a transflective liquid crystal display device), it is only required that the first alignment-sustaining layer 16 and the second alignment-sustaining layer 26 each cover 30% or more and 60% or less of the area of the transmission region of a corresponding one of the first vertical alignment film 14 and the second vertical alignment film 24.

The area covered by the first and second alignment-sustaining layers 16 and 26 (also referred to simply as the “coverage”) is less than 30%, the pretilt direction or the pretilt angle may vary and display non-uniformity may occur, thereby lacking the mass-production stability. On the other hand, if the area covered by the first and second alignment-sustaining layers 16 and 26 is greater than 60%, the reliability of the liquid crystal display device may lower. That is, in order to realize a coverage of 60% or more, it is necessary to allow the photopolymerization reaction to proceed sufficiently by setting the content of the photopolymerizable compound to be mixed in the nematic liquid crystal material to be greater than 0.40% by mass of the liquid crystal material and by elongating the light irradiation time, for example. Then, the content of the photopolymerizable compound remaining in the liquid crystal layer is increased. Alternatively, if a long light irradiation is performed in order to sufficiently lower the content of the photopolymerizable compound remaining in the liquid crystal layer, the alignment film or the organic interlayer insulating film may optically deteriorate to generate a decomposition gas, thereby producing bubbles in the liquid crystal material, for example.

It is preferred that the content of the photopolymerizable compound remaining in the liquid crystal layer 32 is greater than 0.015% by mass and less than 0.068% by mass of the liquid crystal material. If the content of the remaining photopolymerizable compound is 0.068% by mass or more of the liquid crystal material, the photopolymerizable compound polymerizes over time using the liquid crystal display device to act to fix the alignment of the liquid crystal molecules at that point, which may change the pretilt angle of the liquid crystal molecules. A region where the pretilt angle of the liquid crystal molecules is different will exhibit a different brightness during a display operation, and may therefore be observed as display burn-in or display non-uniformity. For example, if the pretilt angle of liquid crystal molecules in a region displaying white decreases, the brightness of the region becomes higher than the surrounding area, and the image which has been displayed in white may therefore appear to have been burned-in. In order for the content of the remaining photopolymerizable compound to be 0.015% by mass or less of the liquid crystal material, it is necessary to reduce the amount of the photopolymerizable compound to be mixed in initially, but then may be impossible form the alignment-sustaining layers 16 and 26 or the function as the alignment-sustaining layers 16 and 26 may not be exerted sufficiently.

In order to control the content of the remaining photopolymerizable compound in the liquid crystal layer 32 within a range of greater than 0.015% by mass and less than 0.068% by mass of the liquid crystal material, it is preferred that the content of the photopolymerizable compound in the mixture for forming the liquid crystal layer 32 is within a range of greater than 0.15% by mass and 0.40% by mass or less of the liquid crystal material. If the content of the photopolymerizable compound is greater than 0.40% by mass, so much light irradiation that the alignment film, etc., are optically deteriorated will be needed in order to decrease the content of the remaining photopolymerizable compound. If the content of the photopolymerizable compound in the mixture for forming the liquid crystal layer 32 is 0.15% by mass or less of the liquid crystal material, it may be impossible to form the alignment-sustaining layers 16 and 26 or the function as the alignment-sustaining layers 16 and 26 may not be exerted sufficiently.

The photopolymerizable compound may be a monomer, an oligomer or a mixture thereof. Diacrylate or dimethacrylate may be preferably used as the monomer. It is preferred that ultraviolet rays (e.g., rays at 365 nm) are used for polymerization, instead of using an initiator.

Next, with reference to FIGS. 2(a) to 2(c), 3(a) and 3(b), a method for manufacturing the liquid crystal display device 100 according to an embodiment of the present invention will be described.

First, as shown in FIG. 2(a), a liquid crystal cell 100a is provided, including a first substrate 10′ with a first electrode and a first vertical alignment film (not shown in this figure) formed thereon, a second substrate 20′ with a second electrode and a second vertical alignment film (not shown in this figure) formed thereon, and, a mixture of a nematic liquid crystal material having a negative dielectric anisotropy and a photopolymerizable compound provided between the first substrate 10′ and the second substrate 20′. Note that the first, substrate 10 and the second substrate 20 shown in FIG. 1(a) are obtained if an alignment-sustaining layer is formed on the surface of the vertical alignment film of the first substrate 10′ and that of the second substrate 20′.

The liquid crystal cell 100a is produced by a one drop filling method, for example. A drop of a mixture of a nematic liquid crystal material having a negative dielectric anisotropy and a photopolymerizable compound is applied onto the first substrate 10′, with a pattern of a sealant 34 having been drawn in a peripheral portion thereof, under a depressurized atmosphere, and then the second substrate 20′ is attached thereto. Thereafter, the sealant 34 is cured, thereby obtaining the liquid crystal cell 100a.

At this point, liquid crystal molecules 32a of the nematic crystal material exhibit a pretilt angle of about 90° with respect to the surface of the vertical alignment film. Molecules 36a of the photopolymerizable compound (e.g., a diacrylate monomer) are dispersed in a liquid crystal layer 32′.

Next, as shown in FIG. 2(b), the mixture is irradiated with light UV1 in the presence of a voltage applied between a pair of electrodes formed on the first substrate 10′ and the second substrate 20′, i.e., in the presence of a voltage applied through the mixture, thereby forming the photopolymerization products 16a and 26a so as to cover an area of 15% or more of one surface of the vertical alignment film of the first substrate 10′ that is closer to the liquid crystal layer 32′ and one surface of the vertical alignment film of the second substrate 20′ that is closer to the liquid crystal layer 32′. In this process, it is preferred that the photopolymerization products 16a and 26a do not cover an area of 30% or more of one surface of the first vertical alignment film that is closer to the liquid crystal layer 32′ and one surface of the second vertical alignment film that is closer to the liquid crystal layer 32′. An intended pretilt angle is obtained by the photopolymerization products 16a and 26a formed through light irradiation in the presence of an applied voltage. The longer the irradiation time (the greater the amount of irradiation light), the greater the pretilt angle becomes.

FIG. 2(b) schematically shows a state where the liquid crystal molecules 32a have been brought into a predetermined alignment by an inclined electric field generated by the slits (openings) formed in the first electrode and the second electrode. The direction of alignment of the liquid crystal molecules 32a can be controlled by the slits formed in the electrode or protrusions (ribs) of a dielectric material formed on one surface of the electrode that is closer to the liquid crystal layer 32′. By forming the photopolymerization products 16a and 26a so as to cover an area of 15% or more of one surface of the first vertical alignment film that is closer to the liquid crystal layer 32′ and one surface of the second vertical alignment film that is closer to the liquid crystal layer 32′, the alignment of the liquid crystal molecules 32a restricted by the electric field is maintained.

Then, as shown in FIG. 2(c), the mixture is further irradiated with light UV2 in the absence of a voltage applied between the first electrode and the second electrode, thereby further forming photopolymerization product so as to cover an area of 30% or more and 60% or less of one surface of each of the first and second vertical alignment films that is closer to the liquid crystal layer 32. It is preferred that the intensity of light used in this irradiation is lower and the irradiation time is longer than in the previous light irradiation. The amount of monomer remaining in the liquid crystal layer 32 is reduced by the second light irradiation.

An experiment example will now be illustrated.

A nematic liquid crystal material having a negative dielectric anisotropy :is mixed with an amount of a diacrylate monomer that is 0.25% by mass of the liquid crystal material. No initiator is mixed in. For example, SE-5561 or SE8963 from Nissan Chemical Industries, Ltd. is used as the vertical alignment film.

A pair of substrates with the electrode and the vertical alignment film formed thereon are provided, and the mixture is injected therebetween by a one drop filling method, thereby obtaining the liquid crystal cell 100a. The thickness of the liquid crystal layer is 3.5 μm, for example.

It is irradiated with ultraviolet rays whose luminance at 313 nm is about 5 mW/cm² (ultraviolet rays whose wavelength is 310 cm or less are removed by a filter; primary wavelengths are 313 nm, 334 nm and 365 nm) over about 60 to 300 sec from the side of one substrate in the presence of a voltage of 10 V applied to the mixture by using an ultra high pressure mercury lamp. Where the first substrate 10′ is a TFT substrate and the second substrate 20′ is a color filter substrate, it is preferred that the irradiation is done from the side of the first substrate 10′. If the irradiation is done from the side of the second substrate 20′, the ultraviolet rays are absorbed by the color filter, resulting in a poor efficiency. Note that the irradiation may be done from both sides. The voltage applied to the mixture may be any voltage as long as it is such a voltage that the liquid crystal molecules 32a are aligned in an intended direction.

Then, the second light irradiation is done in order to reduce the content of the diacrylate monomer remaining in the liquid crystal layer 32′. For example, it is irradiated with ultraviolet rays whose luminance at 365 nm is about 4 mW/cm² over about 10 to 60 sec from the side of one substrate, as in the first light irradiation described above, by using black light. In this process, there is no need to apply a voltage to the mixture.

By being irradiated with ultraviolet rays over a relatively long time as described above, the diacrylate monomer remaining in the liquid crystal layer 32′ further polymerizes to thereby form photopolymerization product so as to cover an area of 30% or more of the surface of the vertical alignment film. Note that since the initial content of the diacrylate monomer in the mixture is 0.25% by mass (0.40% by mass or less) of the liquid crystal material, the coverage will not be greater than 60%.

FIG. 3(a) shows an SEM image showing the condition on the alignment film after the first light irradiation step in the manufacturing method of the experiment example described above, and FIG. 3(b) shows an SEM image showing the condition on the alignment film after the second light irradiation step. They are both images obtained by performing a predetermined light irradiation step, thereafter disassembling the liquid crystal cell, removing the liquid crystal material, and observing, through SEM, the surface after it is rinsed with a solvent.

As shown in FIG. 3(a), polymerization product particles are formed on the vertical alignment film. The diameters of the polymerization product particles, regarded as being spheres, were in the range of about 50 nm to about 100 nm. The coverage calculated based on the area of white portions obtained by digitizing the SEM image was 17.8%. The amount of the remaining monomer at this point was about 0.13% by mass of the liquid crystal material, indicating that about 50% of the monomer mixed in had been reacted. Note that the amount of the remaining monomer was obtained based on the following expression using a gas chromatography (GC).

Remaining monomer amount−(Post-irradiation peak monomer area/Pre-irradiation peak monomer area)×Pre-irradiation monomer amount

The coverage after the second light irradiation shown in FIG. 3(b) was 40.1%. The diameters of the polymerization product particles were in the range of about 50 nm to about 100 nm. The amount of the remaining monomer was about 0.0375 by mass of the liquid crystal material, indicating that about 85% of the monomer mixed in had been reacted

As a result of these experiments conducted under various conditions, it was found that the pretilt of the liquid crystal molecules is stable and display non-uniformity is not observed if the coverage of the alignment-sustaining layer eventually attained is 30% or more and 60% or less. It was also found that display burn-in does not occur if the content of the monomer remaining in the liquid crystal layer is less than 0.068% by mass of the liquid crystal material. Moreover, the problem of bubbles generated in the liquid crystal material did not occur.

### INDUSTRIAL APPLICABILITY

The present invention is applicable to a liquid crystal display device using the PSA technology and a method for manufacturing the same.

### REFERENCE SIGNS LIST

10, 20 Substrate
11, 21 Glass substrate
12, 22 Electrode
14, 24 Vertical alignment film
16, 26 Alignment sustaining layer
16a, 26a Photopolymerization product particle
32 Liquid crystal layer
32a Liquid crystal molecules

34 Sealant

100 Liquid crystal display device

1. A liquid crystal display device comprising a plurality of pixels each having a transmission region, each of the plurality of pixels comprising: a first electrode;
a second electrode; a liquid crystal layer provided between the first electrode and the second electrode; a first vertical alignment film provided between the first electrode and the liquid crystal layer; a second vertical alignment film provided between the second electrode and the liquid crystal layer; and a pair of alignment-sustaining layers of photopolymerization products formed on one surface of the first vertical alignment film that is closer to the liquid crystal layer and one surface of the second vertical alignment film that is closer to the liquid crystal layer, wherein the photopolymerization product of each of the pair of alignment-sustaining layers covers 30% or more and 60% or less of an area of the transmission region of a corresponding one of the first and second vertical alignment films.

2. The liquid crystal display device according to claim 1, wherein the liquid crystal layer includes a nematic liquid crystal material having a negative dielectric anisotropy and a photopolymerizable compound for forming the photopolymerization product, wherein a content of the photopolymerizable compound is greater than 0.015% by mass and less than 0.068% by mass of the liquid crystal material.

3. The liquid crystal display device according to claim 1, wherein the photopolymerization product substantially includes only particles whose particle diameter is 500 nm or less.

4. The liquid crystal display device according to claim 1, wherein the photopolymerizable compound includes diacrylate or dimethacrylate.

5. A method for manufacturing, the liquid crystal display device according to claim 1, comprising the steps of:
(a) providing a liquid crystal cell including a first substrate having the first electrode and the first vertical alignment film formed thereon, a second substrate having the second electrode and the second vertical alignment film formed thereon, and a mixture of a nematic liquid crystal material and a photopolymerizable compound between the first substrate and the second substrate;
(b) irradiating the mixture with light in presence of a voltage applied between the first electrode and the second electrode to form the photopolymerization product so as to cover an area of 15% or more of the transmission region of one surface of each of the first and second vertical alignment films that is closer to the liquid crystal layer; and
(c) further irradiating the mixture with light in absence of a voltage applied between the first electrode and the second electrode after the step (b) to further form the photopolymerization product so as to cover an area of 30% or more of the transmission region of one surface of each of the first and second vertical alignment films that is closer to the liquid crystal layer.

6. The method for manufacturing a liquid crystal display device according to claim 5, wherein a content of the photopolymerizable compound is in a range of 0.15% by mass or more and 0.40% by mass or less of the liquid crystal material in the step (a).
